(19) United States
(12) Patent Application Publication
(10) Pub. No.: US 2026/0105232 A1
(43) Pub. Date: Apr. 16, 2026

(54) EFFICIENT MULTI-DESIGN CIRCUIT OPTIMIZATION

(71) Applicant: International Business Machines Corporation, Armonk, NY (US)

(72) Inventors: David Wells Winston, Asheville, NC (US); Robert Perricone, New City, NY (US); Bria Matthews, Austin, TX (US); LAN LUO, South Burlington, VT (US); Andrew D. Davies, Rochester, MN (US)

(21) Appl. No.: 18/916,877

(22) Filed: Oct. 16, 2024

(51) Int. Cl. G06F 30/337; G06F 30/3308

(52) U.S. Cl. CPC G06F 30/337; G06F 30/3308

(57) ABSTRACT

This is an approach for complex circuit design optimization. Custom circuit optimization for complex circuit can require simulations across numerous conditions and quickly becomes intractable. The approach herein may provide a way to generate netlists based on input parameters and organize circuit simulations of the generated netlists to generate an objective function, which an optimization engine can ultimately utilize. Further the approach herein of the complex circuit optimization may include steps to receive a circuit optimization specification input. Generate a plurality of netlists, based on the circuit optimization specification inputs. Organize the plurality of netlists and a plurality of queues for simulation. Simulate the plurality of netlists in each queue by a remote compute node. Combine simulation results into one or more objective function for use by an optimization engine.

### BACKGROUND

The present invention relates to circuit design, and more specifically, to circuit design optimization.

Computer-aided design (CAD) has revolutionized the way complex electronic circuits are designed. CAD allows for speed, precision, and efficiency in a traditionally laborious process. In circuit design the process begins with defining the desired functionality of the circuit. Designers utilize schematic capture software to draw a visual representation of the circuit using standardized symbols for components (transistors, resistors, capacitors, etc.) and interconnections. This schematic acts as the blueprint, outlining the relationships between different elements. The next step involves translating this schematic into a netlist—a textual representation listing all the interconnected nodes in the circuit. Each node represents a connection point where signals can be transferred, and the netlist describes how these nodes are linked together.

Simulation of circuits involves creating models that mimic the behavior of individual components or entire circuits with computer aided design software. These models can be SPICE (Simulation Program with Integrated Circuit Emphasis), which is a widely used framework for simulating electronic circuits. Another model is Verilog-AMS (VHDL Analog Mixed-Signal): A language extension for Verilog HDL that enables analog and mixed-signal simulations. Simulations can fall into one of three categories, performance evaluation, troubleshooting, and optimization. In performance evaluation, simulations help predict a design's performance under various conditions: speed and power consumption, noise immunity and susceptibility, and interference and crosstalk. In troubleshooting, simulation-based debugging helps identify and fix issues early in the design process. Finally, in optimization, simulating different design variations, designers can optimize their designs for specific requirements, for example, performance (e.g., frequency response), power consumption, and area utilization to name a few.

### SUMMARY

Embodiments of the present invention may comprise a computer-implemented method, a computer system, and a computer program product for efficient multi-design circuit optimization. Embodiments may include receiving a circuit optimization specification input. Further, embodiments may include generating a plurality of netlists, based on the circuit optimization specification inputs. Further yet, embodiments, may include, organizing the plurality of netlists and a plurality of queues for simulation. Additionally, embodiments may include simulating the plurality of netlists in each queue by a remote compute node. Embodiments may also include combining simulation results into one or more objective function for use by an optimization engine.

### BRIEF DESCRIPTION OF THE DRAWINGS

FIG. 1, is a block diagram depicting an exemplary computing environment, in accordance with an embodiment of the invention.

FIG. 2A is a block diagram depicting an exemplary system for multi-design circuit optimization, in accordance with an embodiment of the invention.

FIG. 2B is a block diagram depicting data-driven multi-design circuit optimization engine 200, in accordance with an embodiment of the invention.

FIG. 3 is a flowchart, depicting the steps for efficient multi-design circuit optimization, in accordance with an embodiment of the invention.

### DETAILED DESCRIPTION

Embodiments of the present invention recognize the advantages of efficient multi-design circuit optimization. A complete custom circuit optimization can require simulations across numerous conditions (e.g., PVT, circuit operating models, circuit analysis, circuit types, etc. . . . ). Each simulation condition may require independent simulations, while depending on a shared set of optimization parameters (i.e., features). It would be advantageous to have a framework which efficiently manages multiple circuit simulations in an optimization flow, while simultaneously enabling a circuit designer to generate additional complex circuit optimization scenarios.

Multi-design circuit optimization is a process where circuits with multiple sub-circuit components (e.g., a system on chip with numerous components performing different functions) are simultaneously considered and optimized for various performance criteria. This allows for exploring several different circuit architectures or implementations for use cases. While simultaneous optimization can consider performance metrics such as speed, power consumption, area (i. e, physical size), cost, and reliability. Techniques used in multi-design circuit optimization may include genetic algorithms, simulated annealing, and particle swarm optimization. Genetic algorithms are evolutionary algorithms inspired by natural selection and are used to iteratively improve circuit design. Simulated annealing explores a design space through gradual cooling of the search process, allowing the process to escape local minima and discover global solutions. Particle swarm optimization uses a swarm of particles to explore a design space and eventually converge on an optimal solution.

Embodiments provide a multi-design circuit optimization framework to handle efficiently multiple independent simulations while grouping designs. Further, a framework may divide the overall design space into logical regions or clusters based on shared characteristics. For example, one cluster might focus on high-speed operation, another on low power consumption. Additionally, embodiments of the framework may employ a strategy that considers both global and local optimization. In global optimization, framework may seek optimal parameter sets across all clusters (conditions). This ensures a balance between performance targets for different scenarios. In local optimization, each cluster fine-tunes parameters to maximize performance for that specific condition.

Embodiments of the present invention may incorporate parallel simulation execution. To accelerate the optimization process, multiple independent simulations are run in parallel. Each simulation uses shared parameter sets and focuses on a designated cluster/condition. This is enabled by modern hardware with multi-core processors (e.g., GPUs, TPUs, etc.) and is essential for this parallelization. In an embodiment, the simulation results can be aggregated back, informing subsequent optimization iterations. The engine uses advanced techniques (e.g., surrogate modeling) to predict performance based on limited data, speeding up the exploration of the design space. It should be noted, the underlying structure is defined by how simulations are partitioned based on shared conditions and parameter sensitivities. The framework may continuously evaluate designs across all clusters and continuously refine the parameter sets to achieve an optimal solution that balances performance across different scenarios.

There are several applications of multi-design circuit optimization, some of these applications include digital circuit design (e.g., processors, memory controllers, networking controllers, etc.), analog circuit design (amplifiers, filters, oscillators, light sensors, etc.), and mixed signal circuit design.

In an embodiment, multiple components work together to map a user-specified optimization feature space into a collection of netlist parameters that are applicable to two or more independent netlists, run simulations with those netlist parameters while leveraging parallelism and simulation re-use, and map the results of those simulations back to a user-specified objective function. Typically, grouping designs into a single netlist results in significantly larger runtimes, many times rendering the optimization problem impractical. Embodiments of the invention batch the processing of multiple circuit designs efficiently, resulting in smaller runtimes.

In an embodiment, the components may comprise an input-to-netlist mapper. An input-to-netlist mapper translates a user's high-level description of design features into concrete netlist parameters. A netlist is a textual representation of a circuit, specifying its components and connections. In other words, netlists abstract away the physical implementation details of the circuit, focusing on the logical connections between components. For example, a user may provide an input description of a circuit using standardized language (e.g., hardware description language such as Verilog or VHDL) or format, such as a behavioral description (i.e., defining how the circuit works without specifying the exact components) or schematic description (i.e., a visual representation of the circuit's structure and connections). The mapping process analyses the user's input and translates it into a textual representation of each individual component (e.g., transistors, resistors, capacitors, etc.,), the specific electrical characteristics of each component, and the manner in which each component is connected. The result is a netlist file that can be utilized by an electronic design automation tool used for processes such as simulation, layout design, and fabrication. Benefits of using an input-to-netlist mapper include automation, resulting in a reduction in user error, and verification, where the mapper performs checks for design errors and inconsistencies during the translation process.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

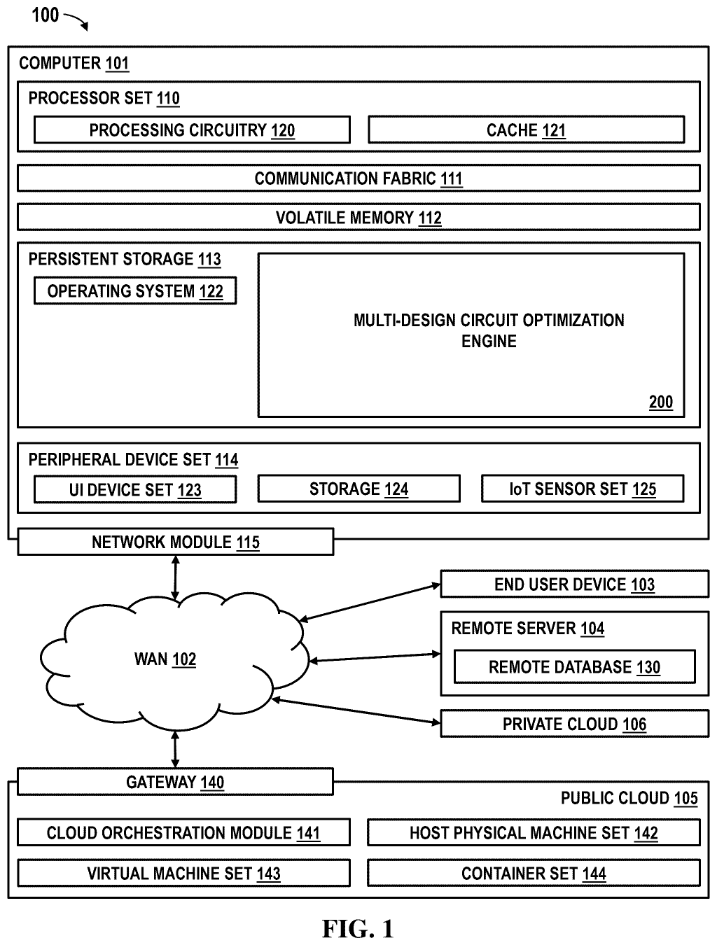

Now with reference to FIG. 1. FIG. 1 depicts Computing environment 100. Computing environment 100 contains an example of an environment for the execution of at least some of the computer code involved in performing the inventive methods, such as multi-design circuit optimization engine 200. In addition to multi-design circuit optimization engine 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and multi-design circuit optimization engine 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in multi-design circuit optimization engine 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid-state storage devices. Operating system 122 may take several forms, such as various known proprietary operating systems or open-source Portable Operating System Interface-type operating systems that employ a kernel. The code included in data-driven cutout engine 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data (e.g., historical netlist knowledge), then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

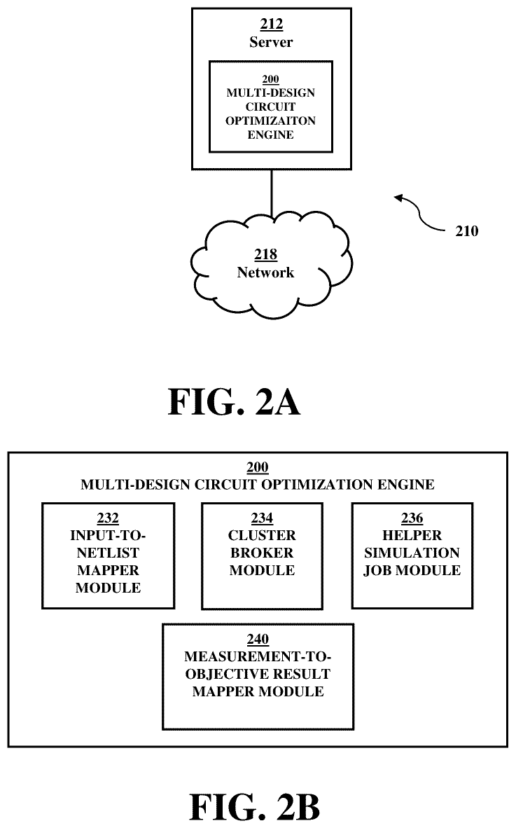

With reference now to FIG. 2A. FIG. 2A is a block diagram 210 depicting a system for data-driven cutout generation, in accordance with an embodiment of the invention. Shown in FIG. 2A is server 212 and network 218. Shown operational on server 212 is Multi-design circuit optimization engine 200.

Multi-design circuit optimization engine 200 is a computer program that can generate objective function outputs from optimization specification inputs. Multi-design circuit optimization engine 200 can be a stand-alone entity or it can be a part of a process design kit model.

With reference now to FIG. 2B. FIG. 2B is a block diagram depicting multi-design circuit optimization engine 200, in accordance with an embodiment of the invention. Shown operational on multi-design circuit optimization engine 200 are input-to-netlist mapper module 232, cluster broker module 234, helper simulation job module 236, and measurement-to-objective result mapper module 240.

Input-to-netlist mapper module 232 is a computer module that can be operational on multi-design circuit optimization engine 200. In an embodiment, input-to-netlist mapper module 232 can receive user specified circuit descriptions (e.g., behavioral description, schematic description, or in hardware description language). In an embodiment, input-to-netlist mapper module 232 analyze the user specified circuit and generate multiple netlist mappings. The netlist mapping is a textual representation of the physical layout and structure of the circuit.

Cluster broker module 234 is a computer module with access to one or more machines in a remote computing environment. Netlist simulations generated by the input-to-netlist mapper may have different runtime/memory characteristics, leverage circuit re-use, etc. The cluster broker manages which compute node handles which simulation netlists. This is done through the use of “smart queues” which ensures each remote machine simulates its required set of simulations most efficiently.

A simulation helper job module 236 is an instance of a circuit simulation process running on a remote cluster machine. In an embodiment, Simulation helper job module 236 is responsible for simulating a series of netlists coming from the smart queues populated by cluster broker 234. The helper job produces the individual circuit measurements described in the netlist and passes those measure for use in the optimization objective function. The simulation helper jobs module 236 can stop the simulation if the cluster is not performing above a threshold.

Measurement-to-objective result mapper module 240 is a computer module that can translate the measurements of the simulations into the objective function that will be input into the optimization engine. For example, measurement-to-objective mapper module 240 can receive the clusters of netlist maps that successfully completed the simulation under the scrutiny of simulation job helper module 236. Based on the measurements of the simulations, measurement-to objective result mapper can identify or generate an objective function corresponding to the parameters of the user which can be input into the optimization engine. In turn, the optimization engine can determine the netlist with the optimal structure based on the parameters.

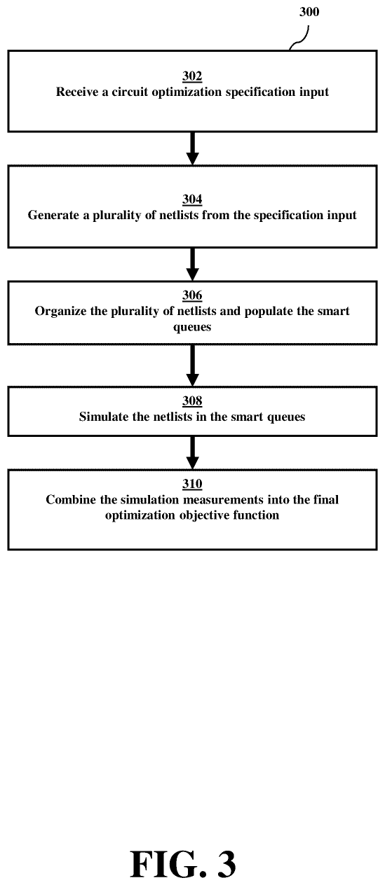

With reference now to FIG. 3. FIG. 3 is flowchart 300 depicting the steps for complex circuit optimization. At step 302, input-to-netlist mapper module 232 receives a circuit optimization specification input. At step 304, input-to-netlist mapper module 232 generates a plurality of netlists, based on the circuit optimization specification inputs. At step 306, the cluster broker module 234 organizes the plurality of netlists according to potential circuit reuse, runtime/memory characteristics, etc. and populates the smart queues. Smart queues can used by individual helper jobs to simulate the netlists. At step 308, the helper simulation jobs module 236 simulates the netlists populated in the smart queues. At step 310, the measurement-to-objective result mapper combines the simulation measurements in the final optimization objective function. It should be noted, measurement-to-objective result mapper module 240 can generate an objective function within the parameter space for the optimization specification based on the feature parameters and/or the results of the simulation.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A computer-implemented method for complex circuit optimization, the computer-implemented method comprises:
receiving a circuit optimization specification input;
generating a plurality of netlists, based on the circuit optimization specification inputs;
organizing the plurality of netlists and a plurality of queues for simulation;
simulating the plurality of netlists in each queue by a remote compute node; and
combining simulation results into one or more objective function for use by an optimization engine.

2. The computer-implemented method of claim 1, further comprising:
generating an objective function based at least in part on the simulation.

3. The computer-implemented method of claim 1, wherein organizing the plurality of netlists further comprises:
generating a smart queue for a plurality of clusters, based on historical netlist knowledge.

4. The computer implemented method of claim 2, further comprising:
generating an optimized circuit design, based on the objective function.

5. The computer-implemented method of claim 1, wherein the circuit optimization specification input is for a system on chip circuit.

6. The computer implemented method of claim 1, wherein the circuit optimization specification is in a hardware description language.

7. The computer-implemented method of claim 1, wherein generating the objective function is based on one or more output measurements of the simulation.

8. A computer system for complex circuit optimization, the computer system comprises:
a memory; and
a processor in communication with the memory, the processor being configured to perform operations to:
receive a circuit optimization specification input;
generate a plurality of netlists, based on the circuit optimization specification inputs;
organize the plurality of netlists and a plurality of queues for simulation;
simulate the plurality of netlists in each queue by a remote compute node; and
combine simulation results into one or more objective function for use by an optimization engine.

9. The computer system of claim 8, further comprising operations to:
generate an objective function based at least in part on the simulation.

10. The computer system of claim 8, wherein organizing the plurality of netlists, further comprises operations to:
generate a smart queue for a plurality of clusters, based on historical netlist knowledge.

11. The computer system of claim 9, further comprising operations to:
generate an optimized circuit design, based on the objective function.

12. The computer system of claim 8, wherein the circuit optimization specification input is for a system on chip circuit.

13. The computer system of claim 8, wherein the circuit optimization specification is in a hardware description language.

14. The computer system of claim 8, wherein generating the objective function is based on one or more output measurements of the simulation.

15. A computer program product for complex circuit optimization, the computer program product comprising a computer storage device, and program instructions stored on the computer storage device, wherein the program instructions comprise:
program instructions to receive a circuit optimization specification input;
program instructions to generate a plurality of netlists, based on the circuit optimization specification inputs;
program instructions to organize the plurality of netlists and a plurality of queues for simulation;
program instructions to simulate the plurality of netlists in each queue by a remote compute node; and
program instructions to combine simulation results into one or more objective function for use by an optimization engine.

16. The computer program product of claim 15, further comprising program instructions to:
generate an objective function based at least in part on the simulation.

17. The computer program product of claim 15, wherein organizing the plurality of netlists, further comprising program instructions to:
generate a smart queue for a plurality of clusters, based on historical netlist knowledge.

18. The computer program product of claim 16, further comprising program instructions to:
generate an optimized circuit design, based on the objective function.

19. The computer program product of claim 15, wherein the circuit optimization specification input is for a system on chip circuit.

20. The computer program product of claim 15, wherein the circuit optimization specification is in a hardware description language.
